(19) United States
(12) Patent Application Publication
(10) Pub. No.: US 2023/0351068 A1
(43) Pub. Date: Nov. 2, 2023

(54) INTELLIGENT MODULARIZED RECONSTRUCTION SYSTEM FOR SPACECRAFT BASED ON TASK TEXT ANALYSIS

(71) Applicant: Xiangtan University, Xiangtan City (CN)

(72) Inventors: Mingfu Li, Xiangtan City (CN); Wenquan Zhao, Xiangtan City (CN); Linling Li, Xiangtan City (CN); Zhenyu Liu, Xiangtan City (CN); Chenglin Yang, Xiangtan City (CN)

(73) Assignee: Xiangtan University, Xiangtan City (CN)

(21) Appl. No.: 18/309,186

(22) Filed: Apr. 28, 2023

(30) Foreign Application Priority Data
Apr. 28, 2022 (CN) 202210462376.9

(51) Int. Cl. G06F 30/15; B64G 1/22

(52) U.S. Cl. CPC G06F 30/15; B64G 1/22

(57) ABSTRACT

Some embodiments of the disclosure provides an intelligent modularized reconstruction system for a spacecraft based on analysis of a task text. In some examples, the intelligent modularized reconstruction system includes a modularized spacecraft component library, a modularized spacecraft component recommendation subsystem, a target spacecraft generation subsystem, and a three-dimensional simulation environment. In other examples, for a new spacecraft reconstruction task, the modularized spacecraft component recommendation subsystem recommends a type and a quantity of required modularized components from the modularized spacecraft component library for input task text. Each modularized component recommended by the modularized spacecraft component recommendation subsystem is used to generate three-dimensional model data of a target spacecraft by the target spacecraft generation subsystem. The three-dimensional simulation environment displays the generated three-dimensional model data of the target spacecraft.

### CROSS REFERENCE TO RELATED APPLICATIONS

This application claims priority to Chinese application number 202210462376.9, filed on Apr. 28, 2022, the disclosure of which is incorporated by reference herein in its entirety.

### FIELD OF THE DISCLOSURE

The disclosure relates generally to the field of intelligent manufacturing. More specifically, the disclosure relates to intelligent modularized reconstruction systems for spacecraft based on task text analyses.

### BACKGROUND

In recent years, with the continuous development of space exploration, a quantity of spacecrafts performing various tasks is becoming larger, and a structure of a spacecraft is becoming more complex. However, an ability of accepting in-orbit service is largely unconsidered for the current spacecraft, and a design philosophy of an integral design and disposable use is generally used. Therefore, it is very difficult for the spacecraft to receive service and implement some space operation of in-orbit maintenance. Problems of a conventional spacecraft such as a long task response time and a low component reuse rate are also becoming more prominent. To solve such problems and meet the need of space development, it is necessary for a future spacecraft to introduce concepts such as a modularized component, a standardized interface, and an intelligent reconstruction system. Modularization is an effective means to enhance the ability of accepting in-orbit service of the spacecraft, and the intelligent reconstruction system will solve prominent problems such as the long task response time and the low component reuse rate of the conventional spacecraft.

In addition, it is difficult or impossible to launch some large structures and spacecrafts from the ground to space, and it is necessary to consider the printing of parts in space by launching raw materials from the ground by using a currently developing additive manufacturing technology. Therefore, there is an urgent need to introduce an intelligent modularized reconstruction system for the spacecraft for space manufacturing, in which parts can be flexibly produced in space to reconstruct large facilities such as a robot, a large spacecraft, an astronomical telescope, and an astronomical observation center by using additive equipment in space.

At the same time, in order to make a reconstruction task described more detailed, the reconstruction task can generally be described in a form of text. Therefore, task text can be analyzed by using current technologies such as natural language processing and deep learning, and key information thereof can be mined to assist a reconstruction technology of the spacecraft, which plays an important role in smoothly performing the task

### SUMMARY

The following presents a simplified summary of the invention in order to provide a basic understanding of some aspects of the invention. This summary is not an extensive overview of the invention. It is not intended to identify critical elements or to delineate the scope of the invention. Its sole purpose is to present some concepts of the invention in a simplified form as a prelude to the more detailed description that is presented elsewhere.

In some embodiments, the disclosure provides an intelligent modularized reconstruction system for a spacecraft based on a task text analysis, where the system includes a modularized spacecraft component library, a modularized spacecraft component recommendation subsystem, a spacecraft generation subsystem, and a three-dimensional simulation environment.

The modularized spacecraft component library includes three-dimensional models and geometric and physical parameters of modularized components.

The modularized spacecraft component recommendation subsystem is configured to recommend a type and a quantity of required modularized components from the modularized spacecraft component library for input task text.

The spacecraft generation subsystem is configured to intelligently reconstruct and assemble the modularized components recommended by the modularized spacecraft component recommendation subsystem to generate three-dimensional model data of a target spacecraft.

The three-dimensional simulation environment is used for displaying and analyzing three-dimensional models of the modularized components recommended by the modularized spacecraft component recommendation subsystem and a three-dimensional model of the target spacecraft generated by the spacecraft generation subsystem.

Specific steps of a new spacecraft reconstruction task are as follows:
Step 1: The spacecraft reconstruction task is described in text to form task text, where content of the task text includes at least a task purpose, a motility requirement, an energy supply, a space size, and a load requirement.
Step 2: The task text is input into the modularized spacecraft component recommendation subsystem, and the subsystem recommends a type and a quantity of modularized components required for the task from the modularized spacecraft component library.
Step 3: The recommended modularized components are displayed in the three-dimensional simulation environment, and initial geometric and structural information of the modularized components is identified and obtained in the three-dimensional simulation environment, to form a component data set.
Step 4: The component data set is input into the spacecraft generation subsystem to perform intelligent reconstruction and assembly, generate the three-dimensional model data of the target spacecraft, and then import the three-dimensional model data of the target spacecraft into the three-dimensional simulation environment for display and analysis.

The modularized spacecraft component library is an extensible database, including at least three-dimensional models and geometric and physical parameters of various modularized components, and the various modularized components each include a standard docking interface. The various modularized components include a propulsion module, an energy module, a storage module, a communication module, an observation module, a connection module, and the like. The standard docking interface enables at least stable inter-module connections, electrothermal transmission, and data communication. Geometric and physical parameters of the modularized components include, but are not limited to, module material, module weight, space size, centroid, and rotational inertia.

Design of each modularized component type in the modularized spacecraft component library may be performed by collecting and arranging related data of spacecraft reconstruction tasks executed over the years, to design, according to functional characteristics and future business requirements of a spacecraft in different tasks, a propulsion module responsive to motility requirements of the reconstruction tasks, an energy module responsive to energy requirements of the reconstruction tasks, a storage module responsive to space requirements of the reconstruction tasks, a communication module responsive to communication requirements of the reconstruction tasks, an observation module responsive to observation requirements of the reconstruction tasks, and a connection module satisfying connection requirements of module components.

The modularized spacecraft component recommendation subsystem includes a text preprocessing module, a component type recommendation module and a component quantity recommendation module. The text preprocessing module is configured to convert text of a reconstruction task into a text vector. The component type recommendation module inputs the text vector corresponding to the reconstruction task, and outputs a type of a modularized component required by the reconstruction task. The component quantity recommendation module inputs the text of the reconstruction task, the output result of the component type recommendation module, and the geometric and physical parameters of the modularized components in the modularized spacecraft component library, and outputs a quantity of modularized components of various types.

Steps of establishing the component type recommendation module in the modularized spacecraft component recommendation subsystem are as follows:
Step a: constructing a task text data set, and collecting and describing each executed spacecraft manufacturing task in text, where one task corresponds to one piece of text, and content of each piece of text includes at least a task purpose, a motility requirement, an energy requirement, a space requirement, and a type of each modularized component used by the spacecraft for performing the task; where the type of each modularized component is represented by a vector, and the vector is used as a label of corresponding text; and forming, by all text and the label of the corresponding text, the task text data set.
Step b: performing text preprocessing on the task text data set, such as Chinese word segmentation, removing stop words, and related operation of text vectorization.
Step c: dividing the preprocessed task text data set into a training set and a verification set; setting proportions of the training set and the verification set through a parameter μ, where a value range of the μ is 0<μ<1, and if μ·100% of the task text data set is used as a training set, the remaining (1−μ)·100% is used as a verification set.
Step d: constructing a deep learning model, training the deep learning model by using text data in the training set as a model input and a corresponding label vector as a model output, and adjusting, by the verification set, a parameter in the deep learning model.

In the step a, a vector is configured to represent the type of the modularized components used by the spacecraft for performing the task. A specific method is as follows: A quantity of N of module types in the modularized spacecraft component library is counted, and an N-dimensional vector is created; positions of N elements in the vector successively correspond to N types of module components in the modularized spacecraft component library; and if corresponding module types in the text exist, an element at the position in the vector is set to 1, otherwise, 0.

The deep learning model in the step d uses text data as an input, an overall model structure is in an architectural form of two-way GRU and Attention in sequence, and finally a full connection layer composed of N neurons is used to output a result. An activation function using the sigmoid function as a model is used, and then multi-class cross entropy is used to calculate a loss function of the model. The model learns information in the text through a GRU input layer and an Attention intermediate layer, and finally the full connection layer in combination with the activation function is used to perform multi-class prediction on the result. A value of the loss function is reduced by adjusting super parameters, such as a learning rate and a batch size, to reversely update weight of the model, so as to continuously optimize an overall model, so that prediction accuracy of a trained model on the verification set reaches 98% or more.

The spacecraft generation subsystem includes a deep neural network model, an input of the deep neural network model is a component data set and an output is three-dimensional model data of a target spacecraft assembled by the modularized component, and training steps of the deep neural network model are as follows:
Step 4a: normalizing each modularized component in the component data set one by one, and assuming xᵢ as a geometric and structural information vector of the i^{th} modularized component, such that the component data set is stored in a form of {xᵢ}ᵢ₌₁^{N}, where N is a total quantity of modularized components included in the data set.
Step 4b: establishing a deep neural network model, and performing initialized training on the model by using the component data set {xᵢ}ᵢ₌₁^{N} as an input and three-dimensional model data of a reconstructed and assembled target spacecraft as an output.
Step 4c: during training, importing the three-dimensional model data of the target spacecraft output each time into the three-dimensional simulation environment for display and performing evaluation in manners including scoring an output result of the model by a related professional person.
Step 4d: reversely optimizing the overall deep neural network model by using the evaluation score value in step 4c, and repeatedly training until the three-dimensional model data of the spacecraft is accurately generated.

An overall model structure of the deep neural network model in step 4b successively uses a convolutional layer, a pooling layer, and a GNN architecture layer, and finally uses a full connection layer to output a result. The first, second, and fourth layers of an initial neural network are convolutional layers, the third layer is the pooling layer, the fourth layer is followed by the GNN architecture layer, and finally the full connection layer is connected. The model performs a preliminary feature extraction on input module component data by using the convolutional layer, after the preliminary feature extraction, performs down sampling by using the pooling layer, then extracts a deeper-level feature by using the convolutional layer, then explicitly performs continuous module component assembly and refinement in a coarse-to-fine manner on a deep-level module feature by using a graph neural network (GNN), and finally outputs three-dimensional model data of an assembled component by using the full connection layer. The skilled person adopts a 10-point system to score the output result, continuously adjusts super parameters such as a quantity of hidden layers of the deep neural network to reversely update the weight through a score result to optimize the overall model, performs repeated training until the output result of the deep neural network model may reach a score of more than 9.5, and then stops the training.

### DETAILED DESCRIPTION

The following describes some non-limiting exemplary embodiments of the invention with reference to the accompanying drawings. The described embodiments are merely a part rather than all of the embodiments of the invention. All other embodiments obtained by a person of ordinary skill in the art based on the embodiments of the disclosure shall fall within the scope of the disclosure.

In some embodiments, the disclosure provides an intelligent modularized reconstruction system for a spacecraft based on a task text analysis, where the system may include a modularized spacecraft component library, a modularized spacecraft component recommendation subsystem, a spacecraft generation subsystem, and a three-dimensional simulation environment.

The modularized spacecraft component library may include three-dimensional models and geometric and physical parameters of modularized components.

The modularized spacecraft component recommendation subsystem is configured to recommend a type and a quantity of required modularized components from the modularized spacecraft component library for input task text.

The spacecraft generation subsystem is configured to intelligently reconstruct and assemble the modularized components recommended by the modularized spacecraft component recommendation subsystem to generate three-dimensional model data of a target spacecraft.

The three-dimensional simulation environment is used for displaying and analyzing three-dimensional models of the modularized components recommended by the modularized spacecraft component recommendation subsystem and a three-dimensional model of the target spacecraft generated by the spacecraft generation subsystem.

Specific steps of a new spacecraft reconstruction task are as follows:
Step 1: The spacecraft reconstruction task is described in text to form task text, where content of the task text may include at least a task purpose, a motility requirement, an energy supply, a space size, and a load requirement.
Step 2: The task text is input into the modularized spacecraft component recommendation subsystem, and the subsystem recommends a type and a quantity of modularized components required for the task from the modularized spacecraft component library.
Step 3: The recommended modularized components are displayed in the three-dimensional simulation environment, and initial geometric and structural information of the modularized components is identified and obtained in the three-dimensional simulation environment, to form a component data set.

Optionally, the initial geometric and structural information of modularized components is identified and obtained in the Gazebo by using a virtual camera and a radar to form a component data set in a point cloud format.
Step 4: The component data set is input into the spacecraft generation subsystem to perform intelligent reconstruction and assembly, generate the three-dimensional model data of the target spacecraft, and then import the three-dimensional model data of the target spacecraft into the three-dimensional simulation environment for display and analysis.

The modularized spacecraft component library is an extensible database, including at least three-dimensional models and geometric and physical parameters of various modularized components, and the various modularized components each include a standard docking interface. The various modularized components include a propulsion module, an energy module, a storage module, a communication module, an observation module, a connection module, and the like. The standard docking interface enables at least stable inter-module connections, electrothermal transmission, and data communication. Geometric and physical parameters of the modularized components include, but are not limited to, module material, module weight, space size, centroid, and rotational inertia.

Optionally, design of each modularized component type in the modularized spacecraft component library may be performed by collecting and arranging related data of spacecraft reconstruction tasks executed over the years, to design, according to functional characteristics and future business requirements of a spacecraft in different tasks, a propulsion module responsive to motility requirements of the reconstruction tasks, an energy module responsive to energy requirements of the reconstruction tasks, a storage module responsive to space requirements of the reconstruction tasks, a communication module responsive to communication requirements of the reconstruction tasks, an observation module responsive to observation requirements of the reconstruction tasks, and a connection module satisfying connection requirements of module components.

The modularized spacecraft component recommendation subsystem may include a text preprocessing module, a component type recommendation module and a component quantity recommendation module. The text preprocessing module is configured to convert text of a reconstruction task into a text vector. The component type recommendation module inputs the text vector corresponding to the reconstruction task, and outputs a type of a modularized component required by the reconstruction task. The component quantity recommendation module inputs the text of the reconstruction task, the output result of the component type recommendation module, and the geometric and physical parameters of the modularized components in the modularized spacecraft component library, and outputs a quantity of modularized components of various types.

Steps of establishing the component type recommendation module in the modularized spacecraft component recommendation subsystem are as follows:
Step a: constructing a task text data set, and collecting and describing each executed spacecraft manufacturing task in text, where one task corresponds to one piece of text, and content of each piece of text may include at least a task purpose, a motility requirement, an energy requirement, a space requirement, and a type of each modularized component used by the spacecraft for performing the task; where the type of each modularized component is represented by a vector, and the vector is used as a label of corresponding text; and forming, by all text and the label of the corresponding text, the task text data set.
Step b: performing text preprocessing on the task text data set, such as Chinese word segmentation, removing stop words, and related operation of text vectorization.
Step c: dividing the preprocessed task text data set into a training set and a verification set; and setting proportions of the training set and the verification set through a parameter μ, where a value range of the μ is 0<μ<1, and if μ·100% of the task text data set is used as a training set, the remaining (1−μ)·100% is used as a verification set.
Step d: constructing a deep learning model, training the deep learning model by using text data in the training set as a model input and a corresponding label vector as a model output, and adjusting, by the verification set, a parameter in the deep learning model.

Optionally, in the step a, a vector is configured to represent the type of the modularized components used by the spacecraft for performing the task. A specific method is as follows: A quantity of N of module types in the modularized spacecraft component library is counted, and an N-dimensional vector is created; positions of N elements in the vector successively correspond to N types of module components in the modularized spacecraft component library; and if corresponding module types in the text exist, an element at the position in the vector is set to 1, otherwise, 0.

Optionally, the deep learning model in the step d uses text data as an input, an overall model structure is in an architectural form of two-way GRU and Attention in sequence, and finally a full connection layer composed of N neurons is used to output a result. An activation function using the sigmoid function as a model is used, and then multi-class cross entropy is used to calculate a loss function of the model. The model learns information in the text through a GRU input layer and an Attention intermediate layer, and finally the full connection layer in combination with the activation function is used to perform multi-class prediction on the result. A value of the loss function is reduced by adjusting super parameters, such as a learning rate and a batch size, to reversely update weight of the model, so as to continuously optimize an overall model, so that prediction accuracy of a trained model on the verification set reaches 98% or more.

The spacecraft generation subsystem may include a deep neural network model, an input of the deep neural network model is a component data set and an output is three-dimensional model data of a target spacecraft assembled by the modularized component, and training steps of the deep neural network model are as follows:
Step 4a: normalizing each modularized component in the component data set one by one, and assuming xᵢ as a geometric and structural information vector of the i^{th} modularized component, such that the component data set is stored in a form of {xᵢ}ᵢ₌₁^{N}, where N is a total quantity of modularized components included in the data set.
Step 4b: establishing a deep neural network model, and performing initialized training on the model by using the component data set {xᵢ}ᵢ₌₁^{N} as an input and three-dimensional model data of a reconstructed and assembled target spacecraft as an output.
Step 4c: during training, importing the three-dimensional model data of the target spacecraft output each time into the three-dimensional simulation environment for display and performing evaluation in manners including scoring an output result of the model by a related professional person.
Step 4d: reversely optimizing the overall deep neural network model by using the evaluation score value in step 4c, and repeatedly training until the three-dimensional model data of the spacecraft is accurately generated.

Optionally, an overall model structure of the deep neural network model in step 4b successively uses a convolutional layer, a pooling layer, and a GNN architecture layer, and finally uses a full connection layer to output a result. The first, second, and fourth layers of an initial neural network are convolutional layers, the third layer is the pooling layer, the fourth layer is followed by the GNN architecture layer, and finally the full connection layer is connected. The model performs a preliminary feature extraction on input module component data by using the convolutional layer, after the preliminary feature extraction, performs down sampling by using the pooling layer, then extracts a deeper-level feature by using the convolutional layer, then explicitly performs continuous module component assembly and refinement in a coarse-to-fine manner on a deep-level module feature by using a graph neural network (GNN), and finally outputs three-dimensional model data of an assembled component by using the full connection layer. The skilled person adopts a 10-point system to score the output result, continuously adjusts super parameters such as a quantity of hidden layers of the deep neural network to reversely update the weight through a score result to optimize the overall model, performs repeated training until the output result of the deep neural network model may reach a score of more than 9.5, and then stops the training.

It should be noted that the content without being described in detail in embodiments of the present disclosure belongs to the conventional technology well known to those skilled in the art.

The foregoing content is merely some embodiments of the present disclosure, and should definitely not be used to limit the protection scope of the present disclosure. Therefore, equivalent changes made in accordance with the claims of the present disclosure shall still fall within the protection scope of the present disclosure.

Various embodiments of the disclosure may have one or more of the following effects. In some embodiments, the present disclosure provides an intelligent modularized reconstruction system for a spacecraft based on a task text analysis, which may quickly respond to a new spacecraft reconstruction task, recommend a type and a quantity of required modularized components, and finally display a three-dimensional model of a target spacecraft.

Many different arrangements of the various components depicted, as well as components not shown, are possible without departing from the spirit and scope of the present disclosure. Embodiments of the present disclosure have been described with the intent to be illustrative rather than restrictive. Alternative embodiments will become apparent to those skilled in the art that do not depart from its scope. A skilled artisan may develop alternative means of implementing the aforementioned improvements without departing from the scope of the present disclosure.

It will be understood that certain features and subcombinations are of utility and may be employed without reference to other features and subcombinations and are contemplated within the scope of the claims. Unless indicated otherwise, not all steps listed in the various figures need be carried out in the specific order described.

The disclosure claimed is:

1. An intelligent modularized reconstruction system for a spacecraft based on analysis of a task text, comprising a modularized spacecraft component library, a modularized spacecraft component recommendation subsystem, a spacecraft generation subsystem, and a three-dimensional simulation environment, wherein:
the modularized spacecraft component library comprises three-dimensional models and geometric and physical parameters of modularized components;
the modularized spacecraft component recommendation subsystem is configured to recommend a type and a quantity of required modularized components from the modularized spacecraft component library for the task text;
the spacecraft generation subsystem is configured to reconstruct and assemble the required modularized components recommended by the modularized spacecraft component recommendation subsystem to generate three-dimensional model data of a target spacecraft;
the three-dimensional simulation environment is configured to display and analyze three-dimensional models of the required modularized components recommended by the modularized spacecraft component recommendation subsystem and three-dimensional models of the target spacecraft generated by the spacecraft generation subsystem; and
the intelligent modularized reconstruction system is configured to perform a spacecraft reconstruction task comprising following steps:
step 1: describing the spacecraft reconstruction task in text to form the task text, wherein the task text comprises at least a task purpose,
a motility requirement, an energy supply, a space size, and a load requirement;
step 2: inputting the task text into the modularized spacecraft component recommendation subsystem, and recommending the type and the quantity of the required modularized components for the task text from the modularized spacecraft component library;
step 3: displaying the required modularized components in the three-dimensional simulation environment, and identifying and obtaining initial geometric and structural information of the required modularized components in the three-dimensional simulation environment to form a component data set; and
step 4: inputting the component data set into the spacecraft generation subsystem to perform reconstruction and assembly, generating three-dimensional model data of the target spacecraft, and importing the three-dimensional model data of the target spacecraft into the three-dimensional simulation environment for display and analysis.

2. The intelligent modularized reconstruction system according to claim 1, wherein:
the modularized spacecraft component library is an extensible database comprising at least three-dimensional models and geometric and physical parameters of various modularized components;
the various modularized components comprise at least one item selected from the group consisting of a propulsion module, an energy module, a storage module,
a communication module, an observation module, and a connection module;
each of the various modularized components comprises a standard docking interface;
the standard docking interface is configured to establish at least one item selected from the group consisting of an inter-module connection, an electrothermal transmission, and a data communication; and
geometric and physical parameters of the various modularized components comprise at least one item selected from the group consisting of module material, module weight, space size, centroid, and rotational inertia.

3. The intelligent modularized reconstruction system according to claim 1, wherein:
the modularized spacecraft component recommendation subsystem comprises a text preprocessing module, a component type recommendation module, and
a component quantity recommendation module;
the text preprocessing module is configured to convert the task text into a text vector;
the component type recommendation module is configured to input the text vector corresponding to the reconstruction task and output a type of a modularized component required by the reconstruction task;
the component quantity recommendation module is configured to receive inputs comprising the task text of the reconstruction task, the type of the modularized component required by the reconstruction task, and the geometric and physical parameters of the modularized components in the modularized spacecraft component library, and to output a quantity of modularized components of various types; and
the component type recommendation module is established by following steps:
step a: constructing a task text data set by:
collecting and describing each executed spacecraft manufacturing task in text, wherein, one task corresponds to one piece of text, and content of each piece of text comprises at least a task purpose,
a motility requirement, an energy requirement, a space requirement, and a type of each modularized component used by the spacecraft for performing the task, the type of each modularized component is represented by a vector, and the vector is used as a label of corresponding text, and
forming the task text data set by all text and the label of the corresponding text;
step b: performing text preprocessing on the task text data set by at least one item selected from the group consisting of Chinese word segmentation, removing stop words, and related operation of text vectorization;
step c: dividing the preprocessed task text data set into a training set and a verification set, and setting proportions of the training set and the verification set through a parameter μ, wherein 0<μ<1, and if μ·100% of the task text data set is used as a training set, a remaining (1−μl)·100% is used as a verification set; and
step d: constructing a deep learning model, training the deep learning model by the preprocessed task text data in the training set as a model input and a corresponding label vector as a model output, and adjusting a parameter in the deep learning model by the verification set.

4. The intelligent modularized reconstruction system according to claim 1, wherein:
the spacecraft generation subsystem comprises a deep neural network model;
an input of the deep neural network model is a component data set and;
an output of the deep neural network model is three-dimensional model data of a target spacecraft assembled by the modularized component; and
the deep neural network model are trained by following steps:
step 4a: normalizing each modularized component in the component data set one by one, wherein xᵢ is a geometric and structural information vector of an i^{th} modularized component, the component data set is stored in a form of {xᵢ}ᵢ₌₁^{N}, and N is a total quantity of modularized components comprised in the data set;
step 4b: establishing a deep neural network model, and performing initialized training on the model by using the component data set {xᵢ}ᵢ₌₁^{N} as the input and using three-dimensional model data of a reconstructed and assembled target spacecraft as the output;
step 4c: during training, importing the output each time into the three-dimensional simulation environment for display and evaluating in manners comprising scoring the output by a person; and
step 4d: reversely optimizing the deep neural network model by an evaluation score value in step 4c, and repeatedly training until the three-dimensional model data of the spacecraft is generated.
